(19) United States
(12) Patent Application Publication
(10) Pub. No.: US 2025/0258198 A1
(43) Pub. Date: Aug. 14, 2025

(54) Flexural Patterns in Guide Plate Substrates

(71) Applicant: FormFactors, Inc., Livermore, CA (US)

(72) Inventor: Sterling Tadashi Collins, Oakland, CA (US)

(21) Appl. No.: 19/048,773

(22) Filed: Feb. 7, 2025

Related U.S. Application Data
(60) Provisional application No. 63/551,317, filed on Feb. 8, 2024.

(51) Int. Cl. G01R 1/073; G01R 31/28

(52) U.S. Cl. CPC G01R 1/0735; G01R 31/2886

(57) ABSTRACT

Guide plates for vertical probe heads include flexure elements that provide a defined flexibility for otherwise rigid guide plates. Such flexibility can be vertical or lateral. This concept allows several disadvantages of conventional probe heads to be alleviated. For example, a vertically flexible upper guide plate can be used to alleviate issues relating to dropped probes. A vertically flexible lower guide plate can be adjusted in operation to expose more probe length as probes wear in operation.

### CROSS REFERENCE TO RELATED APPLICATIONS

This application claims priority from U.S. Provisional Patent Application 63/551,317 filed Feb. 8, 2024, which is incorporated herein by reference.

### GOVERNMENT SPONSORSHIP

None.

### FIELD OF THE INVENTION

This invention relates to probe arrays for making temporary electrical contact to a device/circuit/wafer under test.

### BACKGROUND

Integrated circuits and the like are often tested in fabrication with specialized test equipment. Such test equipment often includes a probe array configured to make electrical contact to the device under test. One common configuration for such probe arrays is referred to as a vertical probe array, where the lateral positions of the probes are determined by upper and lower guide plates the probes pass through. Each probe passes through corresponding holes in the upper and lower guide plates. Probes in such arrays have tips that make temporary electrical contact to the device under test, and bases which are electrically connected to the space transformer of the test equipment.

FIG. 1 shows an exemplary conventional vertical probe array configuration. Here 102 is the space transformer, 104 is the upper guide plate, 106 is the lower guide plate, and two of the probes are referenced as 108 and 110. Probes 108 and 110 have bases 108b and 110b respectively, and have tips 108t and 110t respectively. Probe bases 108b and 110t contact space transformer 102 via space transformer contacts 112. Probe tips 108t and 110t are configured to make temporary electrical contact to device under test 114.

Presently, vertical probes in such arrays are typically “floating” (i.e., they may occupy a range of vertical positions in the gap between the upper guide plate 104 and the space transformer 102). Although this freedom can be helpful for compensating for assembly tolerances and lack of planarity in the upper guide plate 104 and/or space transformer 102, it can also lead to an undesirable issue of “dropped probes” (i.e., probes which have moved so that they no longer make electrical contact to the space transformer (as shown by probe 110 on FIG. 1). Additionally, this gap is difficult to set up during manufacturing and makes spring head (SH) swapping difficult. Here the spring head is the assembly of the probes and the guide plates. Accordingly, it would be an advance in the art to alleviate this issue of dropped probes.

### SUMMARY

In one example of this work, a vertically compliant guide plate is used to provide a restoring force tending to push dropped probes back into contact with the space transformer. Further variations of this main idea include, but are not limited to: A guide plate for testing a multi-die device under test where the guide plate has independent flexure elements for each die; controlled lateral compliance of a guide plate; and providing a range of motion of a flexible lower guide plate.

Significant advantages are provided.
1) Eliminate or drastically curtail dropped probe failures, although this solution will not eliminate residual gaps between space transformer and upper guide plate due to curvatures of either feature. The upper guide plate will tip/tilt adjust to the space transformer surface, but it will not be able to conform to the space transformer surface if curvature of either surface is significant. Therefore, some residual float may exist in certain areas of the array, its magnitude governed by the respective flatnesses of the two components, but no longer dependent on the relative tolerance stackup between them, nor on their relative angles.
2) Large active area support-reduced sensitivity to planarity.
3) Faster mechanical assembly-simplified or eliminated gap measurements between probe bases and the space transformer.
4) Improved Springhead interchangeability-No more float adjustments.
5) Improved contact resistance-Increased contact force at probe base/space transformer contact.
6) This approach provides a simpler replacement of shimmed movable guide plate systems.

### BRIEF DESCRIPTION OF THE DRAWINGS

FIG. 1 shows the problem of dropped probes that can arise in conventional vertical probe arrays.

FIGS. 2A-B shows exemplary guide plates for use in embodiments of the invention.

FIGS. 3A-D show an example of how the issue of dropped probes can be alleviated in an embodiment of the invention.

FIG. 4 shows an embodiment of the invention including separate force/displacement control of the upper guide plate.

FIGS. 5A-C show an embodiment of the invention having a flexible lower guide plate.

FIG. 6 shows another exemplary guide plate for use in embodiments of the invention.

### DETAILED DESCRIPTION

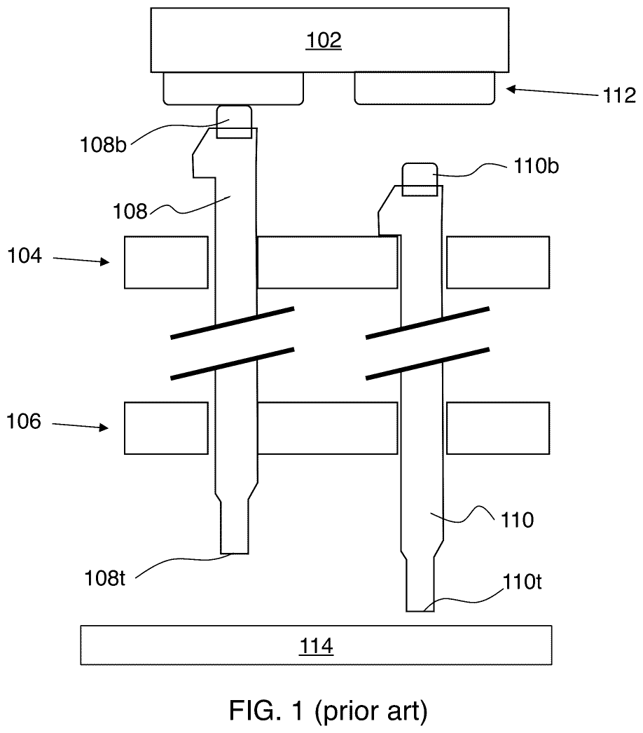

FIG. 1 shows the problem of dropped probes that can arise in conventional vertical probe arrays. All current 2D MEMS (microelectricalmechanical) probes are “floating”—probes can move vertically in the gap between upper guide plate and space transformer. Conventionally, this is required for assembly tolerances, and to compensate for planarity variation in the upper guide plate and space transformer.

When probes are pushed or pulled to varying positions in this gap, spring head planarity and usability degrades, causing critical issues for customers (especially Dropped Probes). Significant assembly time is spent indirectly ensuring this gap is set correctly. Adjusting this gap requires lengthy assembly and disassembly operations. The gap must be checked and adjusted for each unique spring head/probe card pair. Here a probe card is the combination of spring head, space transformer, and backing printed circuit assembly (including mechanical support components). On FIG. 1, 108 is a probe in proper position and 110 is a “dropped probe”.

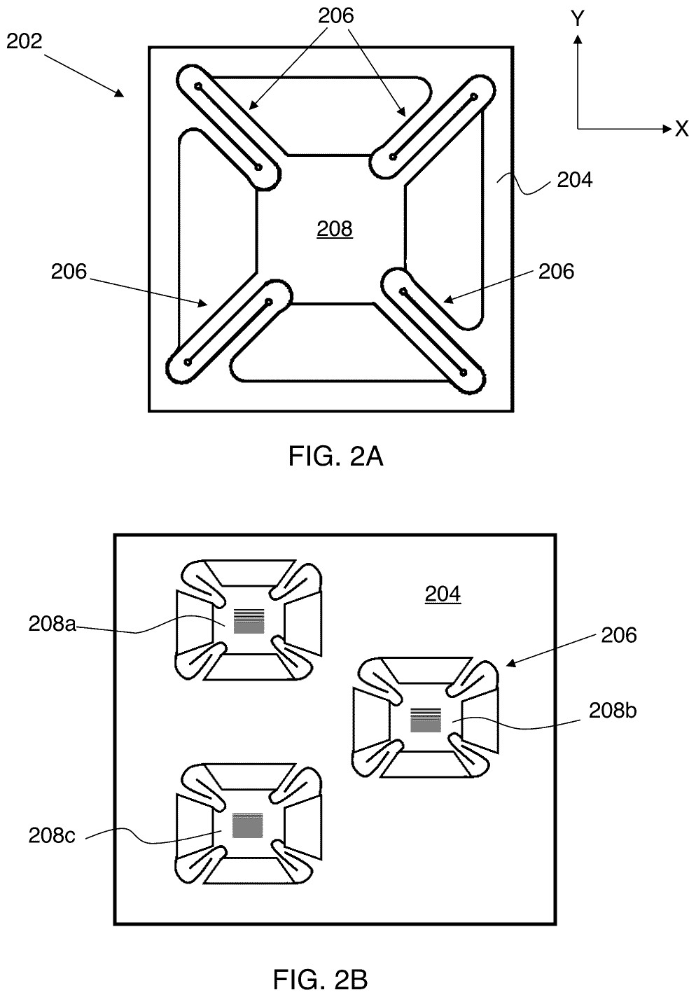

FIGS. 2A-B shows exemplary guide plates for use in embodiments of the invention. The basic idea is to use flexural elements designed into the guide plate itself. FIG. 2A shows a first example of this. Here 202 is the flexural guide plate (it can be the upper and/or lower guide plate of a probe card), 204 is a rigid guide plate frame, 208 is a rigid probe array section, and 206 are the flexure members connecting frame 204 to probe array section 208. The flexure configuration of this example allows Z-deflections (into or out of the plane of FIG. 2A), without sacrificing XY alignment (i.e., the lateral alignment of section 208 is preserved). The lateral directions X and Y on FIG. 2A are indicated by the axes. The serpentine beams for flexures 206 provide compliance with minimal strain (which is often required if brittle materials are used).

To address planarity discrepancies between dies (groups of probes), this approach may be implemented repeatedly around each die, allowing each group of probes to conform to the local underlying substrate. FIG. 2B shows an example, where plates 208a, 208b, 208c can individually tip/tilt to match their respective dies.

In general, we expect that inclusion of structures or profiles in a guide plate to allow the plate to flex, move in a controlled way, conform to underlying substrates, or apply preloading force to probes will be useful. The description below provides several examples of this.

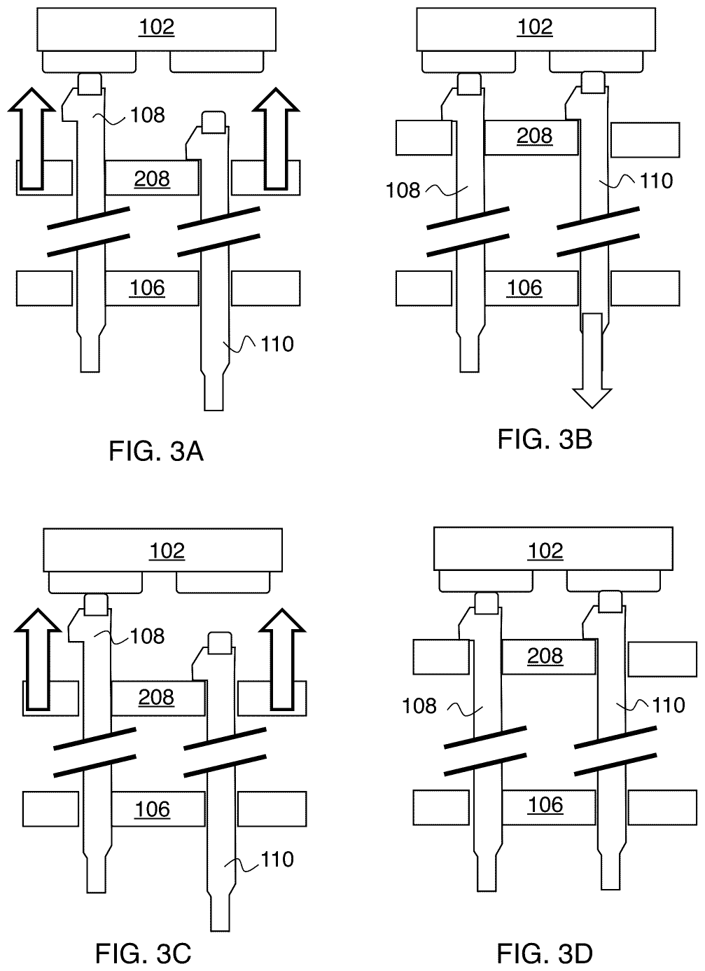

FIGS. 3A-D show an example of how the issue of dropped probes can be alleviated in an embodiment of the invention. The transition from FIG. 3A to FIG. 3B shows the upper guide plate preload pushing probe 110 into contact with space transformer 102. If a probe is then pulled downwards, towards its tip (as shown by probe 110 on FIG. 3C), the planarity of the probe array is restored by the upper guide plate preload, which returns the probes to their correct vertical positions (FIG. 3D) (which also corrects the dropped probe of FIG. 3C).

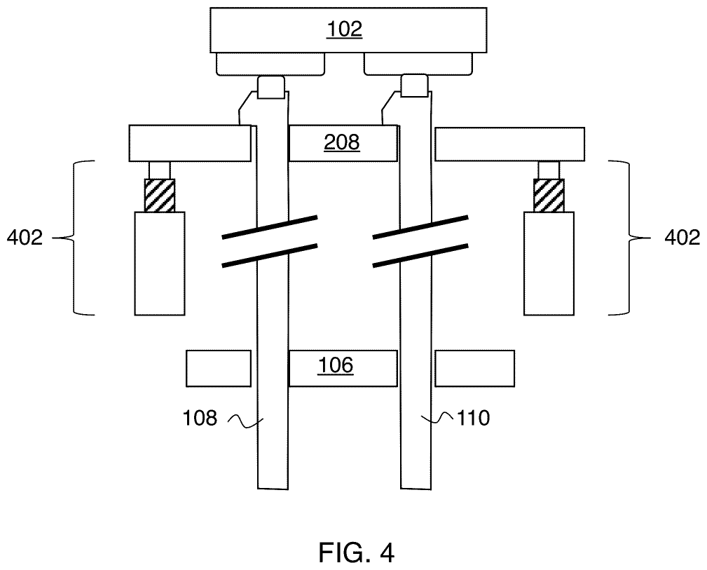

FIG. 4 shows an embodiment of the invention including separate force/displacement control of the upper guide plate. In certain situations, where additional force is required, an external mechanism may be used to control the preload force and/or displacement of the guide plate. FIG. 4 schematically shows an example of this, where actuators 402 provide the indicated force and/or displacement control of guide plate section 208. Any force/displacement actuator known in the art can be used for this function.

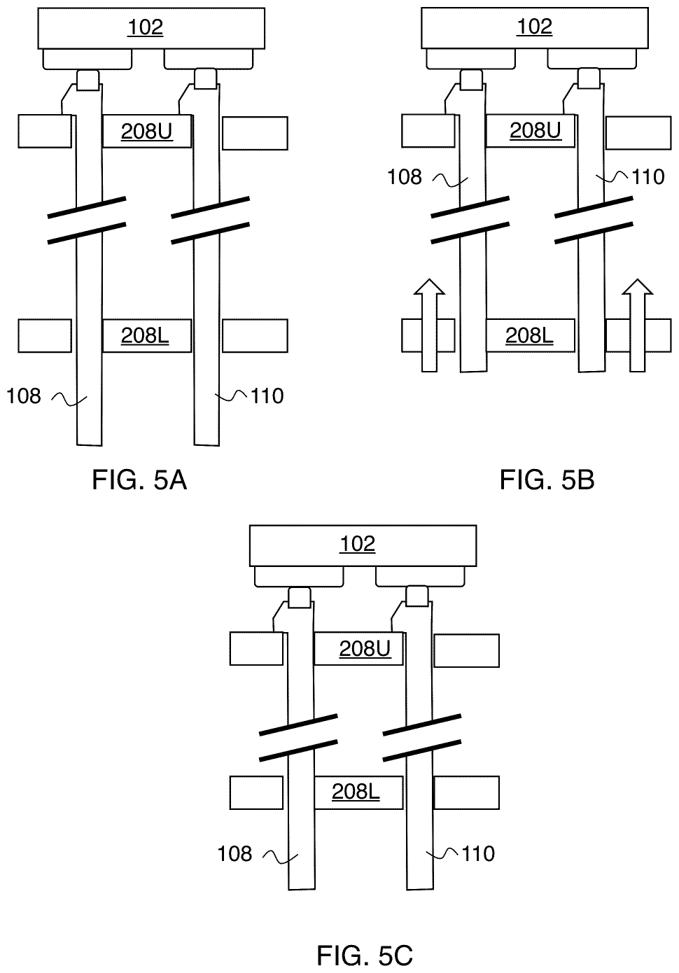

FIGS. 5A-C show an embodiment of the invention having a flexible lower guide plate. Here 208U is a rigid probe array section of a flexible upper guide plate as described above, and 208L is a rigid probe array section of a flexible lower guide plate. Under normal conditions, probe tips wear down, eventually becoming too short to function (transition from FIG. 5A to FIG. 5B). At this point, by moving the lower guide plate upward (transition from FIG. 5B to FIG. 5C), more tip length can be exposed, thereby extending the life of the probe card. The actuator for such position control can be any displacement actuator known in the art. By implementing this motion in a flexible lower guide plate, we simplify otherwise complex assemblies that conventionally require many components and careful assembly steps.

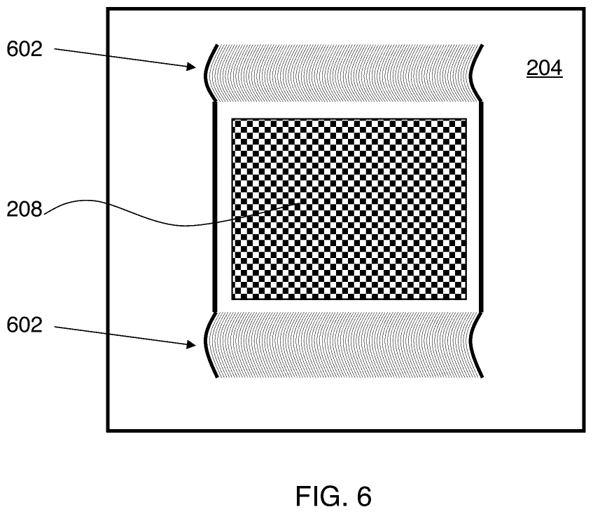

FIG. 6 shows another exemplary guide plate for use in embodiments of the invention. To allow controlled lateral motion, thin features 602 may be cut into the plate, which allow a section 208 to shift easily only in one lateral direction (left-right for this example), while constraining motion in other directions. This advantageously replaces more complex assemblies which require separate mechanical plates (spacers) to be shifted and positioned to achieve similar offsets. Such lateral displacements of upper and/or lower guide plates can be useful in assembly and/or servicing of probe cards.

1. A probe head configured to make temporary electrical contact to a device under test, the probe head comprising:
an array of vertical probes, each probe having a tip configured for making temporary electrical contact to the device under test, and each probe having a base opposite its tip;
a space transformer configured to make electrical contact to the bases of the vertical probes;
a lower guide plate having lower guide plate holes corresponding to each of the vertical probes, wherein each vertical probe passes through a corresponding lower guide plate hole in the lower guide plate;
an upper guide plate having upper guide plate holes corresponding to each of the vertical probes, wherein each vertical probe passes through a corresponding upper guide plate hole in the upper guide plate;
wherein the upper guide plate is disposed between the space transformer and the lower guide plate;
wherein at least one of the upper guide plate and lower guide plate includes a flexure mechanism that provides vertical or lateral flexibility.

2. The probe head of claim 1, wherein the upper guide plate includes:
an outer frame;
one or more rigid probe array sections; and
one or more flexural elements connecting the outer frame to the one or more rigid probe array sections such that the rigid probe array sections can flex in a vertical direction, but can't flex in lateral directions, whereby an elastic force is provided to the probes that tends to keep the bases of the probes in electrical contact with the space transformer.

3. The probe head of claim 2, wherein the one or more rigid probe array sections are configured to correspond to separate dies of a wafer under test, whereby each rigid probe array section can flex independently to conform to its corresponding die of the wafer under test.

4. The probe head of claim 2, further comprising:
a preload mechanism mechanically coupled to the upper guide plate and configured to adjust the elastic force and/or a vertical displacement of the upper guide plate.

5. The probe head of claim 1, wherein the upper guide plate includes:
an outer frame;
one or more rigid probe array sections; and
one or more lateral flexural elements connecting the outer frame to the one or more rigid probe array sections;
wherein the one or more lateral flexural elements enable the one or more rigid probe array sections to flex in a predetermined lateral direction.

6. The probe head of claim 1, wherein the lower guide plate includes:
an outer frame;
one or more rigid probe array sections; and
one or more lateral flexural elements connecting the outer frame to the one or more rigid probe array sections;
wherein the one or more lateral flexural elements enable the one or more rigid probe array sections to flex in a predetermined lateral direction.

7. The probe head of claim 1, wherein the lower guide plate includes:
an outer frame;
one or more rigid probe array sections; and
one or more flexural elements connecting the outer frame to the one or more rigid probe array sections such that the rigid probe array sections can flex in a vertical direction, but can't flex in lateral directions.

8. The probe head of claim 7, further comprising:
an adjustment mechanism for the lower guide plate, wherein a vertical separation between at least one of the rigid probe array sections and the upper guide plate can be varied by the adjustment mechanism to account for wear of the vertical probes.
